(19) United States
(12) Patent Application Publication
(10) Pub. No.: US 2012/0288685 A1
(43) Pub. Date: Nov. 15, 2012

(54) THIN-FILM ELEMENT ASSEMBLY

(75) Inventors: Gen Yukawa, Kanagawa (JP); Iwao Yagi, Kanagawa (JP); Makoto Noda, Kanagawa (JP); Mao Katsuhara, Kanagawa (JP)

(73) Assignee: SONY CORPORATION, Tokyo (JP)

(21) Appl. No.: 13/460,903

(22) Filed: May 1, 2012

(30) Foreign Application Priority Data
May 12, 2011 (JP) 2011-107287

(51) Int. Cl. B32B 3/08

(52) U.S. Cl. 428/172; 428/189

(57) ABSTRACT

A thin-film element assembly includes: a base having flexibility and a plurality of thin-film elements provided on a first surface of the base, wherein a second region where no thin-film element is provided is formed in the base in an outer side of a first region where a plurality of thin-film elements are provided, and wherein convex portions are formed in the second region of the first surface of the base, or the second region of a second surface, or the second region of each of the first and second surfaces.

### FIELD

The present disclosure relates to a thin-film element assembly.

### BACKGROUND

Presently, in image display devices such as display devices having an organic electroluminescent element (organic EL element) or a microcapsule-type electrophoretic display element, or a liquid crystal display device, realization of image display devices having flexibility is desired. Image display devices having flexibility have a large screen and are thin, light, and rollable, and are easy to carry. However, on the other hand, when such an image display device is rolled up, a problem such as the occurrence of scratches or abrasion resulting from friction between contact surfaces is likely to occur.

In order to deal with such a problem, JP-A-2008-185853, for example, discloses a disclosure relating to a flexible display device in which light-emitting elements are formed on a flexible base, and which is rolled up for storage so that a light-emitting-side surface and a rear-side surface are in contact with each other, and in which the hardness of the light-emitting-side surface is larger than the hardness of the rear-side surface.

### SUMMARY

However, in the flexible display device disclosed in JP-A-2008-185853, a further improvement in durability is desired.

Therefore, it is desirable to provide a thin-film element assembly having a configuration and structure capable of achieving a further improvement in durability.

In a thin-film element assembly of an embodiment of the present disclosure, a plurality of thin-film elements are provided on a first surface of a base having flexibility, a second region where no thin-film element is provided is formed in the base in an outer side of a first region where a plurality of thin-film elements are provided, and convex portions are formed in the second region of the first surface of the base, or the second region of a second surface, or the second region of each of the first and second surfaces.

In the thin-film element assembly of the embodiment of the present disclosure, since the convex portions are formed in the second region of the base where no thin-film element is provided, even when the thin-film element assembly is rolled up, it is possible to reliably prevent the second surface of the base from making contact with the plurality of thin-film elements formed on the first surface, and to provide more durability to the thin-film element assembly.

### BRIEF DESCRIPTION OF THE DRAWINGS

FIG. 1A is a schematic side view of a thin-film element assembly according to a first embodiment as seen from a first direction, and FIG. 1B is a schematic perspective view of the thin-film element assembly as seen from a second surface side.

FIG. 2A is a schematic perspective view of the thin-film element assembly according to the first embodiment as seen from a first surface side, and FIG. 2B is a schematic perspective view of a thin-film element assembly according to a second embodiment as seen from a second surface side.

FIG. 3A is a schematic side view of a thin-film element assembly according to a third embodiment as seen from a first direction, and FIG. 3B is a schematic perspective view of the thin-film element assembly as seen from a second surface side.

FIG. 4A is a schematic side view of a thin-film element assembly according to a fourth embodiment as seen from a first direction, and FIG. 4B is a schematic perspective view of the thin-film element assembly as seen from a first surface side.

FIG. 5 is a schematic perspective view of a thin-film element assembly according to a fifth embodiment as seen from a first surface side.

FIGS. 6A and 6B are schematic side views of thin-film element assemblies according to a sixth embodiment and a modification example thereof as seen from a first direction, respectively.

FIGS. 7A and 7B are schematic partial cross-sectional views of thin-film elements according to seventh and eighth embodiments, respectively.

FIGS. 8A and 8B are schematic partial cross-sectional views of thin-film elements according to ninth and tenth embodiments, respectively.

FIG. 9 is a schematic partial cross-sectional view of a thin-film element according to an eleventh embodiment.

FIG. 10A is a schematic partial cross-sectional view of a modification of a thin-film element assembly of an embodiment, and FIG. 10B is a schematic partial cross-sectional view of a support substrate or the like, for explaining a method of manufacturing a thin-film element assembly according to an embodiment.

### DETAILED DESCRIPTION

Hereinafter, the present disclosure will be described based on embodiments by referring to the drawings. However, the present disclosure is not limited to the embodiments, and various numerical values and materials described in the embodiments are only examples. The description will be given in the following order.

1. Overall Description of Thin-Film Element Assembly according to Present Disclosure

2. First Embodiment (Thin-Film Element Assembly according to Present Disclosure)

3. Second Embodiment (Modification of First Embodiment)

4. Third Embodiment (Another Modification of First Embodiment)

5. Fourth Embodiment (Still Another Modification of First Embodiment)

6. Fifth Embodiment (Modification of Fourth Embodiment)

7. Sixth Embodiment (Modifications of First and Fourth Embodiments)

8. Seventh Embodiment (Modifications of First to Sixth Embodiments)

9. Eighth Embodiment (Another Modification of First to Sixth Embodiments)

10. Ninth Embodiment (Still Another Modification of First to Sixth Embodiments)

11. Tenth Embodiment (Still Another Modification of First to Sixth Embodiments)

12. Eleventh Embodiment (Still Another Modification of First to Sixth Embodiments) and Alternative Embodiment

### Overall Description of Thin-Film Element Assembly According to Present Disclosure

In a thin-film element assembly according to the present disclosure,

a base may have a rectangular shape such that two opposite sides extend in a first direction, and the other two opposite sides extend in a second direction, and

convex portions may be formed in a second region along the two sides extending in the first direction. In such a preferred configuration, the base is rollable about an axial line parallel to the second direction. That is, the base is rollable along the first direction. In such a preferred configuration, each of the convex portions may have a notch portion extending in parallel to the second direction. In these preferred configurations, the thin-film element assembly may have such a structure in which

the convex portions are formed in the second region of a second surface of the base, or the second region of each of the first and second surfaces of the base,

a reinforcing member extending in the second direction is formed in at least a first region of the second surface of the base, and

the height of the reinforcing member is lower than the height of the convex portion formed in the second region of the second surface of the base. In the thin-film element assembly according to the present disclosure including these preferred configurations and structure, the thin-film element assembly may have such a structure in which:

the convex portions are formed in the second region of the first surface of the base or the second region of each of the first and second surfaces of the base, and

additional convex portions are formed in the second region of the first surface of the base along the second sides extending in the second direction. That is, in such a structure, the convex portions are provided in a frame shape in the second region of the first surface of the base so as to surround the first region.

In the thin-film element assemblies according to the present disclosure including the above-described preferred configurations and structures, the convex portions are preferably formed of at least one material selected from a group consisting of an expanded material, a gel-like material, and a rubber-like material. In this case, it is still preferable that the convex portions contain an antistatic agent.

In the thin-film element assemblies according to the present disclosure including the above-described preferred configurations and structures (hereinafter, these will be collectively referred to simply as the “thin-film element assembly according to the present disclosure), although the base has flexibility, the expression “the base has flexibility” means that the base is not broken even when it is rolled around a cylinder having a radius of 5 cm when the base has a thickness of 1 mm or smaller and around a cylinder having a radius of 20 cm when the base has a thickness of 1 mm or more. Moreover, although the thin-film element assembly according to the present disclosure generally has flexibility, the expression “the thin-film element assembly has flexibility” means that the thin-film element assembly is not broken even when it is rolled around a cylinder of a radius of 20 cm.

In the thin-film element assembly according to the present disclosure, examples of the expanded material include urethane foam and acrylic foam, examples of the gel-like material include silicone gel and acrylic gel, and examples of the rubber-like material include silicone rubber, ethylene propylene-diene rubber (EPDM), chloroprene rubber (CR), NBR, SBR, isoprene rubber (IR), and natural rubber, examples of the antistatic agent include carbon, titanium oxide, carbon nanotubes, copper, aluminum, surfactants, an ionic conductivity mechanism, and an electron conduction mechanism. However, the material constituting the convex portions is not limited to the above materials, but plastic material constituting the base described later may be used. In this case, the plastic material constituting the base may be the same as or different from the plastic material constituting the convex portions. The material constituting the reinforcing member may include the above materials, and alternatively, the plastic material constituting the base described later may be used. In this case, the plastic material constituting the base may be the same as or different from the plastic material constituting the reinforcing member. Alternatively, examples of the material constituting the reinforcing member include polyethylene resin (PE), polyethylene terephthalate resin (PET), ethylene vinyl acetate copolymer (EVA), polyvinyl chloride resin (PVC), polypropylene resin (PP), polystyrene resin (PS), acrylonitrile-styrene-butadiene polymerized resin (ABS), cyclic olefin copolymer (COC), polycarbonate resin (PC), polyamide resin (PA), phenolic resins, and TPE.

Examples of a method of manufacturing the convex portion and the reinforcing member include a method of punching a sheet-shaped member with a die, an injection molding method, and an extrusion molding method. The manufactured convex portion and the reinforcing member may be attached to the base using an adhesive, and alternatively, the manufactured convex portion and reinforcing member may be fixed to the base based on a thermal fusion bonding method, a photo-curing method, and a method using a bonding tape. Alternatively, the convex portion and the reinforcing member may be directly formed on the base. Moreover, the convex portions and the reinforcing member may be formed to be integrated with each other, and the convex portion and the reinforcing member may be formed to be integrated with the base. The convex portions may have a strip-like shape, a shape formed by a set of line segments, and a shape formed by a set of dots. The number of convex portions in the second region along one side extending in the first direction may be one or plural. The convex portions formed in the second region of the first surface of the base will be referred to as “first convex portions” for convenience, and the convex portions formed in the second region of the second surface of the base will be referred to as “second convex portions” for convenience.

In the thin-film element assembly according to the present disclosure, examples of the material constituting the base include at least one resin (plastic material or plastic film) selected from the group consisting of polyethylene terephthalate (PET), polyethylene naphthalate (PEN), polyimide, polycarbonate (PC), polyether sulfone, polymethyl methacrylate (poly(methyl methacrylate), PMMA), polyvinyl alcohol (PVA), polyvinyl phenol (PVP), polysulfone, polyether sulfone (PES), and polysulfone imide, and alternatively, thin-film glass, metal foil such as stainless steel foil or aluminum foil, and alloy foil.

In the thin-film element assembly according to the present disclosure, when the height of the convex portion is H, and the distance between the two opposite sides parallel to the first direction of the base is W, the value of H is preferably sufficiently smaller than the value of W. Moreover, in the thin-film element assembly according to the present disclosure, when the height of the reinforcing member is H₃, and the height of the second convex portion is H₂, it is preferable that a relation of H₃<H₂ is satisfied. Moreover, when the thickness of the thin-film element is Hₒ, and the height of the first convex portion is H₁, it is necessary to satisfy a relation of H₀<H₁ and H₀<H₂.

In the thin-film element assembly according to the present disclosure, the thin-film element may be formed of an organic electroluminescence element (organic EL element), and alternatively, may be formed of a microcapsule-type electrophoretic display element or a semiconductor light-emitting element (semiconductor laser element or LED), and alternatively, may be formed of a liquid-crystal display device. The organic EL element, the microcapsule-type electrophoretic display element, the semiconductor light-emitting element, and the liquid-crystal display device may have a known configuration and structure.

Alternatively, in the thin-film element assembly according to the present disclosure, the thin-film element may have a structure including:

a first electrode and a second electrode;

an active layer formed between the first electrode and the second electrode; and

a control electrode facing the active layer with an insulating layer interposed.

In this case, specifically, the thin-film element may have such a structure that the thin-film element is formed of a three-terminal device such as an organic transistor, more specifically, a field-effect transistor (FET) including a thin-film transistor (TFT),

the first and second electrodes correspond to source/drain electrodes,

the control electrode corresponds to a gate electrode,

the insulating layer corresponds to a gate insulating layer,

the active layer corresponds to a channel forming region. Alternatively, the thin-film element may have a structure including:

a first electrode and a second electrode; and

an active layer formed between the first and second electrodes. In this case, more specifically, the thin-film element may have such a structure that the thin-film element is formed of a two-terminal device such as a photoelectric conversion element, a photovoltaic battery, an image sensor, or various sensors including an optical sensor. In these cases, the active layer may have such a configuration that the active layer is formed of an organic semiconductor material, for example.

Examples of an image display device in which the thin-film element assembly according to the present disclosure is assembled include a so-called desktop-type personal computer, a notebook-type personal computer, a mobile-type personal computer, a PDA (personal digital assistance), a mobile phone, a game machine, an e-books, an electronic paper (electronic newspaper), a bulletin board (such as signs, posters, or blackboard), a copy machine, a rewritable paper as a substitute for and printer paper, a calculator, a display unit of home electric appliance, a card display unit of a point card or the like, and various image display devices (such as electronic advertising or e-POP). Moreover, examples thereof include various illumination devices.

When the thin-film element is formed of a bottom-gate and bottom-contact type thin-film transistor, the thin film transistor can be manufactured by the steps of:

(a) forming a gate electrode on a base and then forming a gate insulating layer on an entire surface of the base;

(b) forming source/drain electrodes on the gate insulating layer; and

(c) forming a channel forming region formed of an organic semiconductor material layer on the gate insulating layer positioned at least between the source/drain electrodes. The bottom-gate and bottom-contact type thin-film transistor includes:

(A) a gate electrode formed on a base;

(B) a gate insulating layer formed on the gate electrode and the base;

(C) source/drain electrodes formed on the gate insulating layer; and

(D) a channel forming region formed of an organic semiconductor material layer, on the gate insulating layer between the source/drain electrodes.

Moreover, when the thin-film elements are formed of a bottom-gate and top-contact type thin-film transistor, the thin-film transistor can be manufactured by the steps of:

(a) forming a gate electrode on a base and then forming a gate insulating layer on an entire surface of the base;

(b) forming a channel forming region and a channel forming region extension portion formed of an organic semiconductor material layer, on the gate insulating layer; and

(c) forming source/drain electrodes on the channel forming region extension portion. The bottom-gate and top-contact type thin-film transistor includes:

(A) a gate electrode formed on a base;

(B) a gate insulating layer formed on the gate electrode and the base;

(C) a channel forming region and a channel forming region extension portion formed of an organic semiconductor material layer, on the gate insulating layer; and

(D) source/drain electrodes formed on the channel forming region extension portion.

Furthermore, when the thin-film elements are formed of a top-gate and bottom-contact type thin-film transistor, the thin-film transistor can be formed by the steps of:

(a) forming source/drain electrodes on a base;

(b) forming a channel forming region formed on an organic semiconductor material layer, on the entire surface of the base; and

(c) forming a gate insulating layer on the entire surface of the base and then forming a gate electrode in a portion of the gate insulating layer on the channel forming region. The top-gate and bottom-contact type thin-film transistor includes:

(A) source/drain electrodes formed on a base;

(B) a channel forming region formed of an organic semiconductor material layer, on the base between the source/drain electrodes;

(C) a gate insulating layer formed on the channel forming region; and

(D) a gate electrode formed on the gate insulating layer.

Moreover, when the thin-film elements are formed of a top-gate and top-contact type thin-film transistor, the thin-film transistor can be formed by the steps of:

(a) forming a channel forming region and a channel forming region extension portion formed of an organic semiconductor material layer on a base;

(b) forming source/drain electrodes on the channel forming region extension portion; and

(c) forming a gate insulating layer on an entire surface of the base and then forming a gate electrode in a portion of the gate insulating layer on the channel forming region. The top-gate and top-contact type thin-film transistor includes:

(A) a channel forming region and a channel forming region extension portion formed of an organic semiconductor material layer, on the base;

(B) source/drain electrodes formed on the channel forming region extension portion;

(C) a gate insulating layer formed on the source/drain electrodes and the channel forming region; and

(D) a gate electrode formed on the gate insulating layer.

The thin-film element may have such a structure that a current flowing into the active layer from the first electrode toward the second electrode is controlled by a voltage applied to the control electrode. Specifically, as described above, the thin-film element may have such a configuration that the thin-film element is formed of a field-effect transistor (including a thin-film transistor) in which a control electrode corresponds to a gate electrode, a first electrode and a second electrode correspond to source/drain electrodes, an insulating layer corresponds to a gate insulating layer, and an active layer corresponds to a channel forming region. Alternatively, the thin-film element may have such a configuration that the thin-film element is formed of a light-emitting element (an organic light-emitting element or an organic light-emitting transistor) in which an active layer emits light when a voltage is applied to the control electrode and the first and second electrodes. Here, in the light-emitting element, the organic semiconductor material constituting the active layer has a light-emitting function based on charge storage due to modulation based on the voltage applied to the control electrode and recombination of injected electrons and holes. As the organic semiconductor material constituting the active layer, an organic semiconductor material having p-type conductivity or a non-doped organic semiconductor material can be used broadly. In a light-emitting element (organic light-emitting transistor) in which an active layer is formed of an organic semiconductor material having p-type conductivity, emission intensity is proportional to the absolute value of a drain current and can be modulated by a gate voltage and the voltage between the source/drain electrodes. Whether the thin-film element exhibits the function as a field-effect transistor or a light-emitting element depends on the state (bias) of voltage application to the first and second electrodes. First, when the control electrode is modulated under a condition in which a bias is applied in a range where electrons are not injected from the second electrode, a current flows from the first electrode to the second electrode. This is the operation of transistors. On the other hand, when bias applied to the first electrode and the second electrode is increased under a condition in which holes are sufficiently stored, electron injection starts, and light is emitted by recombination with holes. Alternatively, the thin-film element may have such a configuration that the thin-film element is formed of a photoelectric conversion element in which a current flows between the first electrode and the second electrode by irradiation of the active layer with light. When the photoelectric conversion element is formed of the thin-film element, specifically, a photovoltaic battery or an image sensor can be formed of the photoelectric conversion element. In this case, a voltage may be not applied or may be applied to the control electrode. When a voltage is applied, a flowing current can be modulated by applying a voltage to the control electrode. When the thin-film element is configured as a light-emitting element or a photoelectric conversion element, the configuration and structure of the light-emitting element or the photoelectric conversion element may be the same as any one of the configurations and structures of the four field-effect transistors described above, for example.

Examples of the organic semiconductor material include polythiophene, poly-3-hexylthiophene (P3HT) wherein a hexyl group is introduced into polythiophene, pentacene[2,3,6,7-dibenzoanthracene], dioxaanthanthrene compound including peri-xanthenoxanthene, polyanthracene, naphthacene, hexacene, heptacene, dibenzopentacene, tetrabenzopentacene, chrysene, perylene, coronene, terrylene, ovalene, quoterrylene, circumanthracene, benzopyrene, dibenzopyrene, triphenylene, polypyrrole, polyaniline, polyacetylene, polydiacetylene, polyphenylene, polyfuran, polyindole, polyvinyl carbazole, polyselenophene, polytellurophene, polyisothianaphthene, polycarbazole, polyphenylene sulfide, polyphenylene vinylene, polyphenylene sulfide, polyvinylene sulfide, polythienylene vinylene, polynaphthalene, polypyrene, polyazulene, phthalocyanines represented by copper phthalocyanine, merocyanine, hemicyanine, polyethylene dioxythiophene, pyridazine, naphthalene tetracarboxylic acid diimide, poly(3,4-ethylendioxythiophene)/polystyrenesulfonic acid (PEDOT/PSS), and quinacridone. Alternatively, examples of the organic semiconductor material include a compound selected from a group consisting of condensed polycyclic aromatic compounds, porphyrin derivatives, phenyl vinylidene-based conjugated oligomers, and thiophene-based conjugated oligomers. Specific examples thereof include condensed polycyclic aromatic compound such as acene-based (pentacene, tetracene, or the like), porphyrin molecules, and conjugated oligomers (phenyl vinylidene-based or thiophene-based).

Alternatively, examples of the organic semiconductor material include porphyrin, 4,4′-biphenyldithiole (BPDT), 4,4′-diisocyanobiphenyl, 4,4′-diisocyano-p-terphenyl, 2,5-bis(5′-thioacetyl-2′-thiophenyl)thiophene, 2,5-bis(5′-thioacetyl-2′-thiophenyl)thiophene, 4,4′-diisocyanophenyl, benzidine (biphenyl-4-4′-diamine), TCNQ (tetracyanoquinodimethane), charge-transfer complex represented by tetrathiafulvalene (TTF)-TCNQ complex, bisethylenetetrathiafulvalene (BEDTTTF)-perchloric acid complex, BEDTTTF-iodine complex, and TCNQ-iodine complex, biphenyl-4,4′-dicarboxylic acid, 1,4-di(4-thiophenylacetylinyl)-2-ethylbenzene, 1,4-di(4-isocyanophenylacetylinyl)-2-ethylbenzene, dendrimer, fullerene such as C60, C70, C76, C78, or C84, 1,4-di(4-thiophenylethyl)-2-ethylbenzene, 2,2″-dihydroxy-1,1′:4′,1″-terphenyl, 4,4′-biphenyldiethanal, 4,4′-biphenyldiol, 4,4′-biphenylisocyanate, 1,4-diacetylbenzene, diethylbiphenyl-4,4′-dicarboxylate, benzo[1,2-c;3,4-c′;5,6-c″]tris[1,2]dithiol-1,4,7-trithion, α-sexithiophene, tetrathiotetracene, tetraselenotetracene, tetratelluric tetracene, poly(3-alkyl thiophene), poly(3-thiophene-β-ethane sulfonic acid), poly(N-alkyl pyrrole)poly(3-alkyl pyrrole), poly(3,4-dialkyl pyrrole), poly(2,2′-thienyl pyrrole), and poly(dibenzothiophene sulfide).

The active layer or the channel forming region (organic semiconductor material layer) may contain polymer as necessary. The polymer may be dissolved in an organic solvent. Specifically, examples of the polymer (organic binding agent or binder) include polystyrene, poly-α-methylstyrene, and polyolefin. Furthermore, additives (for example, so-called doping materials such as n-type impurities or p-type impurities) may be added as necessary.

Examples of a solvent for preparing an organic semiconductor material solution includes aromatic series such as toluene, xylene, mesitylene, or tetralin, ketone series such as cyclopentanone or cyclohexanone, and hydrocarbon series such as decalin. Among these, the use of a solvent having a relatively high boiling point such as mesitylene, tetralin, or decalin is preferred from the perspective of transistor characteristics and preventing abrupt drying of the organic semiconductor material during formation of the organic semiconductor material layer.

An application method can be used as a method of forming the active layer, the channel forming region, or the channel forming region and the channel forming region extension portion. Here, any one of general application methods can be used without any problem, and specifically, the following various application methods can be used, for example. That is, examples of the application method include various printing methods, such as a screen printing method, an ink jet printing method, an offset printing method, a reverse offset printing method, a gravure printing method, a gravure offset printing method, a relief printing method, a flexo printing method, and a micro contact method; a spin coating method, various coating methods, such as an air doctor coater method, a blade coater method, a rod coater method, a knife coater method, a squeeze coater method, a reverse roll coater method, a transfer roll coater method, a gravure coater method, a kiss coater method, a cast coater method, a spray coater method, a slit coater method, a slit orifice coater method, a calender coater method, a casting method, a capillary coater method, a bar coater method, and a dipping method; a spray method; a method using a dispenser; and a method (called a stamp method) of applying a liquid material.

Examples of materials constituting the control electrode, the first electrode, the second electrode, the gate electrode, and the source/drain electrodes include metals such as platinum (Pt), gold (Au), palladium (Pd), chromium (Cr), molybdenum (Mo), nickel (Ni), aluminum (Al), silver (Ag), tantalum (Ta), tungsten (W), copper (Cu), titanium (Ti), indium (In), tin (Sn), iron (Fe), cobalt (Co), zinc (Zn), magnesium (Mg), and the like; alloys containing these metal elements; conductive particles composed of these metals; conductive particles of alloys containing these metals; and conductive materials such as impurity-containing polysilicon. A laminated structure of layers containing these elements may be used. Furthermore, examples of materials constituting the control electrode, the first electrode, the second electrode, the gate electrode, and the source/drain electrodes include organic materials (conductive polymer) such as poly(3,4-ethylenedioxythiophene)/polystyrenesulfonic acid [PEDOT/PSS] and polyaniline. The materials constituting the control electrode, the first electrode, the second electrode, the gate electrode, and the source/drain electrodes may be the same or different.

The method of forming the control electrode, the first electrode, the second electrode, the gate electrode, and the source/drain electrodes depends on the constituent materials thereof but may be a combination of a patterning technique as necessary and any one of the above-described various application methods; a physical vapor deposition method (PVD method); a pulsed laser deposition method (PLD), an arc discharge method, various chemical vapor deposition methods (CVD method) including a MOCVD method; a lift-off method; a shadow mask method; and an electroplating method or an electroless plating method, and a combination thereof. Examples of the PVD method include (a) various vacuum evaporation methods, such as an electron beam heating method, a resistance heating method, a flash evaporation method, a method of heating a crucible, and the like; (b) a plasma evaporation method; and (c) various sputtering methods, such as a double-pole sputtering method, a direct-current sputtering method, a direct-current magnetron sputtering method, a high-frequency sputtering method, a magnetron sputtering method, an ion beam sputtering method, a bias sputtering method, and the like; and (d) various ion plating methods, such as a DC (direct current) method, a RF method, a multi-cathode method, an activation reaction method, a field evaporation method, a high-frequency ion plating method, a reactive ion plating method, and the like. When forming a resist pattern, for example, after a resist material is applied to form a resist film, and the resist film is patterned using a photolithography technique, a laser drawing technique, an electron beam drawing technique, or an X-ray drawing technique. The resist pattern may be formed using a resist transfer method. When the control electrode, the first electrode, the second electrode, the gate electrode, and the source/drain electrodes are formed based on an etching method, a dry-etching method or a wet-etching method is adopted. Examples of the dry-etching method include ion milling and reactive ion etching (RIE). Moreover, the control electrode, the first electrode, the second electrode, the gate electrode, and the source/drain electrodes may be formed based on a laser abrasion method, a mask evaporation method, a laser transfer method, and the like.

The insulating layer or the gate insulating layer (hereinafter sometime collectively referred to as the “gate insulating layer or the like”) may include a single layer or plural layers. Examples of a material constituting the gate insulating layer or the like include not only an inorganic insulating material exemplified by a metal oxide high-dielectric insulating film such as silicon oxide-based material; silicon nitride (SiN_{Y}); oxidized aluminum (Al₂O₃); and HfO₂, but also an organic insulating material (organic polymer) exemplified by linear hydrocarbons in which one end has a functional group that can be bonded to the control electrode and the gate electrode (for example, polymethylmethacrylate (PMMA); polyvinyl phenol (PVP); polyvinyl alcohol (PVA); polyimide; polycarbonate (PC); polyethylene terephthalate (PET); polystyrene; silanol derivatives (silane coupling agent) such as N-2(aminoethyl)-3-aminopropyltrimethoxysilane (AEAPTMS), 3-mercaptopropyltrimethoxysilane (MPTMS), or octadecyltrichlorosilane (OTS); octadecanethiol; or dodecyl isocyanate), or a combination thereof. Here, examples of the silicon oxide-based material include oxidized silicon (SiO_{X}), BPSG, PSG, BSG, AsSG, PbSG, silicon oxynitride (SiON), SOG (spin on glass), or a low-permittivity SiO₂-based material (for example, polyarylether, cycloperfluorocarbon polymer and benzocyclobutene, cyclic fluorine resin, polytetrafluoroethylene, arylether fluoride, polyimide fluoride, amorphous carbon, and organic SOG).

The method of forming the gate insulating layer or the like may be a combination of a patterning technique as necessary and any one of the above-described various application methods; a lift-off method, a sol-gel method, an electrodeposition method, and a shadow mask method.

Alternatively, the gate insulating layer may be formed by oxidizing or nitriding the surfaces of the control electrode and the gate electrode or by forming an oxide film or a nitride film on the surfaces of the control electrode and the gate electrode. The method of oxidizing the surfaces of the control electrode and the gate electrode depends on the materials constituting the control electrode and the gate electrode, but, for example, an oxidizing method using O₂ plasma or an anodization method may be used. The method of nitriding the surfaces of the control electrode and the gate electrode depends on the materials constituting the control electrode and the gate electrode, but, for example, a nitriding method using N₂ plasma may be used. Alternatively, with regard to an Au electrode, for example, the gate insulating layer may be formed on the surfaces of the control electrode and the gate electrode by coating the surfaces of the control electrode and the gate electrode with insulating molecules having a functional group that can chemically form a bond with the control electrode and the gate electrode, such as linear hydrocarbons in which one end is modified by a mercapto group in the self-organizing manner by a method such as a dipping method. Alternatively, the gate insulating layer may be formed by modifying the surfaces of the control electrode and the gate electrode by a silanol derivative (silane coupling agent).

### First Embodiment

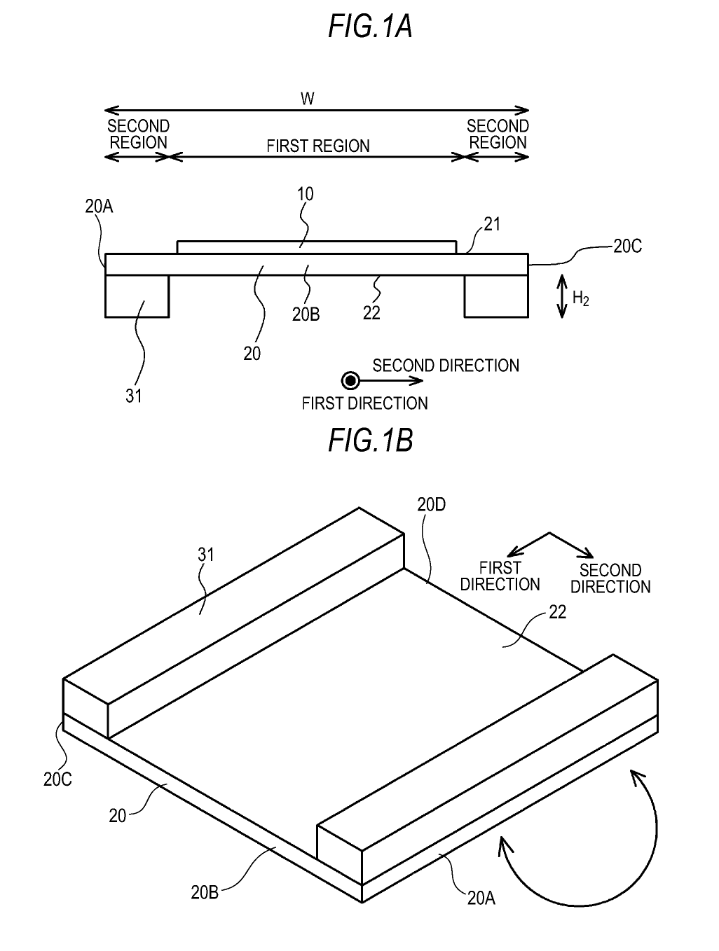

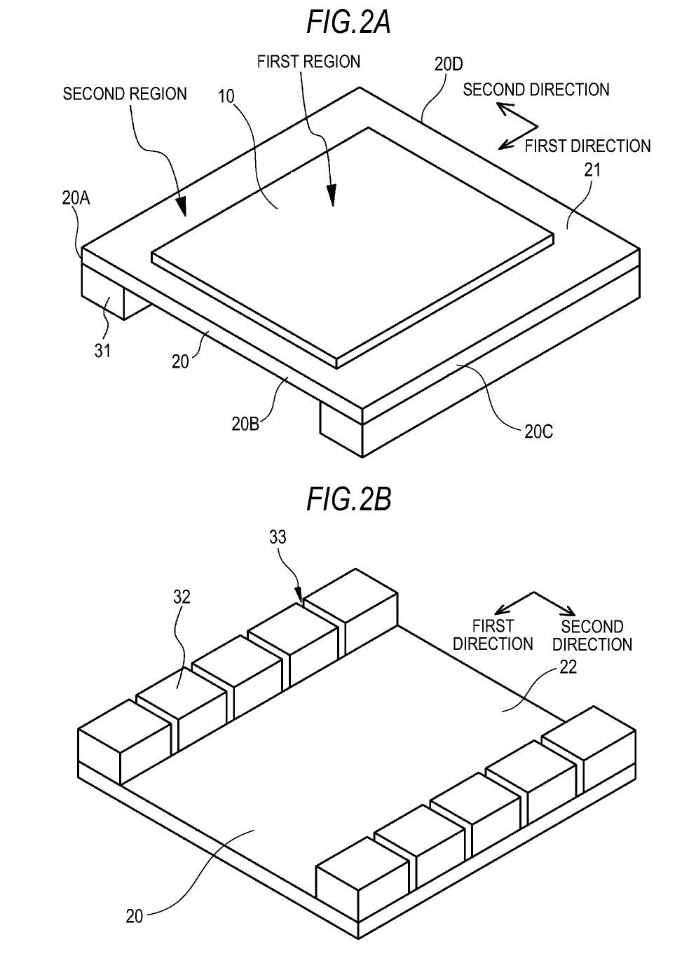

The first embodiment relates to a thin-film element assembly according to the present disclosure. A schematic side view of the thin-film element assembly of the first embodiment as seen from a first direction is shown in FIG. 1A. A schematic perspective view of the thin-film element assembly as seen from a second surface side is shown in FIG. 1B. A schematic perspective view of the thin-film element assembly as seen from a first surface side is shown in FIG. 2A.

In the thin-film element assembly of the first embodiment, a plurality of thin-film elements 10 are provided on a first surface 21 of a base 20 having flexibility. In the base 20, a second region where no thin-film element 10 is provided is formed in an outer side of a first region where the plurality of thin-film elements 10 are provided. Moreover, in the first embodiment, a convex portion (second convex portion 31) is formed in the second region of a second surface 22.

Here, the base 20 is formed of a polyimide resin and has such a rectangular shape that two opposite sides 20A and 20C extend in a first direction, and the other two opposite sides 20B and 20D extend in a second direction. The length of the sides 20A and 20C is set to 140 mm, and the length of the sides 20B and 20D (the distance W between the two opposite sides 20A and 20C parallel to the first direction of the base 20) is set to 76 mm. The second convex portion 31 is manufactured by a method of punching a sheet-shaped member with a die, and the second convex portion 31 is formed in the second region along the two sides 20A and 20C extending in the first direction. The second convex portion 31 has a strip-like shape, and the width thereof is 5 mm, and the length thereof is the same as the length of the sides 20A and 20C. Moreover, the height H₂ of the second convex portion 31 is set to 0.05 mm. That is, H/W=H₂/W=0.05/76. The second convex portion 31 is attached to the base 20 using an adhesive (not shown) formed of an acrylic adhesive. The second convex portion 31 may contain an antistatic agent.

Moreover, the base 20 can be rolled about the axial line parallel to the second direction. That is, the base 20 can be rolled up along the first direction. In the thin-film element assembly of the first embodiment, since the convex portion is formed in the second region of the base where no thin-film element is provided, even when the thin-film element assembly is rolled up, it is possible to reliably prevent the second surface of the base from making contact with the plurality of thin-film elements formed on the first surface. Moreover, it is possible to prevent the occurrence of scratches or damages on the thin-film element and to provide more durability to the thin-film element assembly. In the flexible display device disclosed in JP-A-2008-185853, the present inventors discovered that when a roll-up test was repeatedly performed, the occurrence of scratches or damages on the light-emitting-side surface due to the contact between the light-emitting-side surface and the rear-side surface was not completely prevented.

### Second Embodiment

The second embodiment is a modification of the first embodiment. In the thin-film element assembly of the second embodiment, as shown in FIG. 2B by a schematic perspective view of the thin-film element assembly as seen from the second surface side, each of the convex portions (second convex portions 32) has a notch portion 33 extending in parallel to the second direction. Except for this, since the configuration and structure of the thin-film element assembly of the second embodiment are the same as the configuration and structure of the thin-film element assembly described in the first embodiment, detailed description thereof is not provided. The configuration and structure of the thin-film element assembly of the second embodiment in which the convex portion has the notch portion can be applied to various embodiments described below.

### Third Embodiment

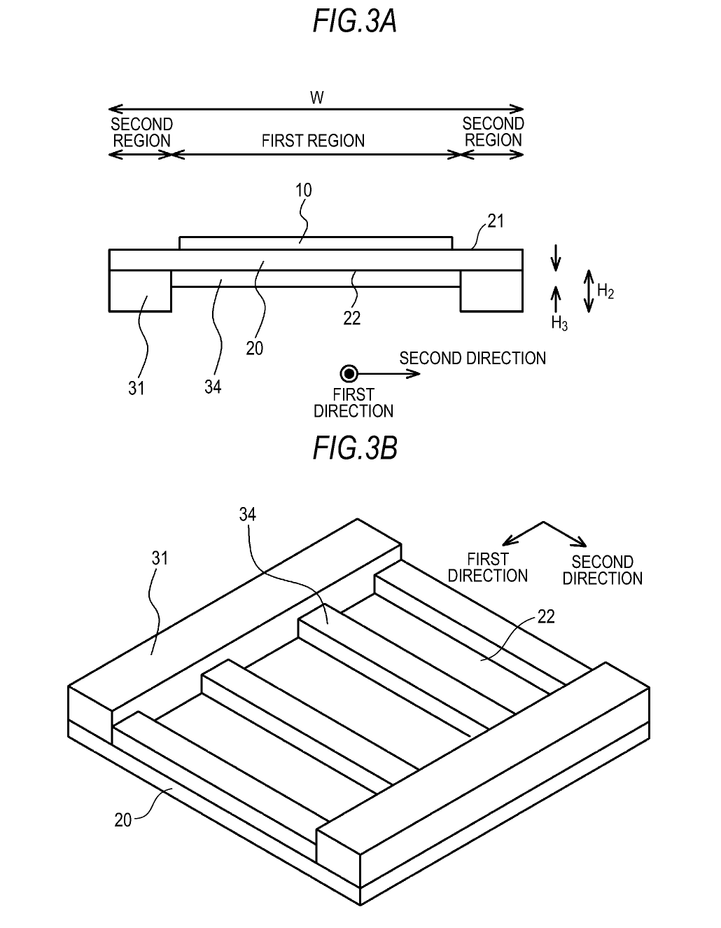

The third embodiment is also a modification of the first embodiment. In the thin-film element assembly of the third embodiment, as shown in FIG. 3A by a schematic side view of the thin-film element assembly as seen from the first direction and in FIG. 3B by a schematic perspective view of the thin-film element assembly as seen from the second surface side,

a reinforcing member 34 extending in the second direction is formed in at least the first region (in the third embodiment, the first and second regions) of the second surface 22 of the base 20, and

the height H₃ of the reinforcing member 34 is lower than the height H₂ of the convex portion (the second convex portion 31) formed in the second region of the second surface 22 of the base 20. Specifically, H₃/H₂=⅓. The reinforcing member 34 is formed of a metallic material and is attached to the base 20 using an adhesive (not shown) formed of an acrylic adhesive. The reinforcing members 34 and the second convex portions 31 are assembled in such a ladder shape that the two second convex portions 31 correspond to the frame of a ladder and the reinforcing members 34 correspond to rungs or steps.

Except for the above, since the configuration and structure of the thin-film element assembly of the third embodiment are the same as the configuration and structure of the thin-film element assembly described in the first embodiment, detailed description thereof will not be provided. The configuration and structure of the thin-film element assembly of the third embodiment in which the reinforcing member is provided on the second surface of the base can be applied to various embodiments described below in which the convex portion is provided on the second surface of the base.

### Fourth Embodiment

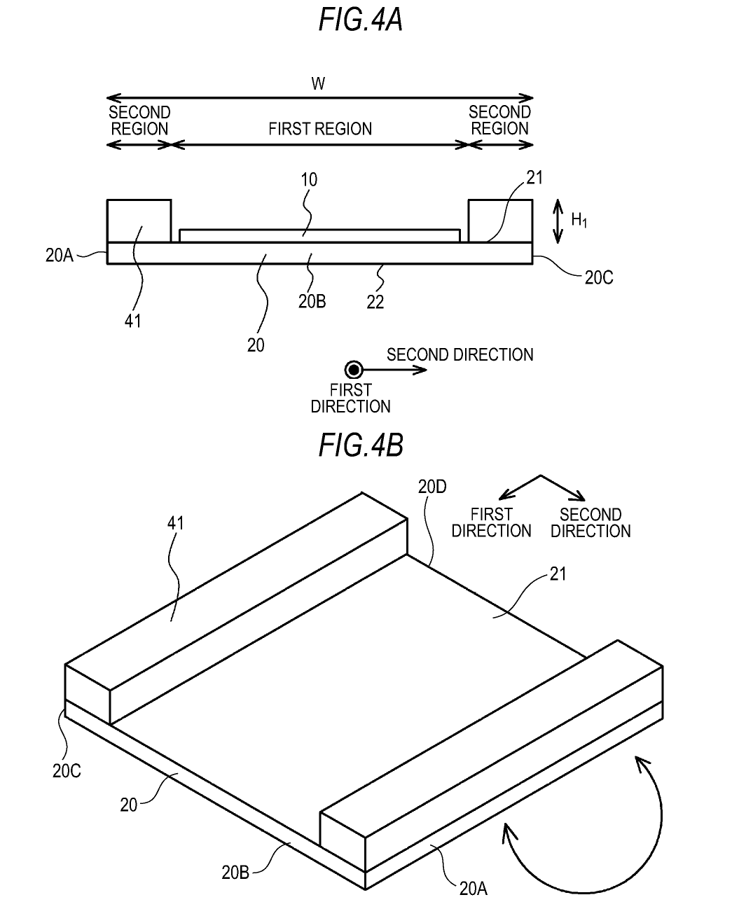

The fourth embodiment is also a modification of the first embodiment. A schematic side view of the thin-film element assembly of the fourth embodiment as seen from the first direction is shown in FIG. 4A, and a schematic perspective view of the thin-film element assembly as seen from the first surface side is shown in FIG. 4B. In the thin-film element assembly of the fourth embodiment, a convex portion (first convex portion 41) is formed in the second region of the first surface 21 of the base 20. Except for this, since the configuration and structure of the thin-film element assembly of the fourth embodiment are the same as the configuration and structure of the thin-film element assembly described in the first embodiment, detailed description thereof is not provided. The first convex portion 41 is formed in the second region along the two sides 20A and 20C extending in the first direction.

### Fifth Embodiment

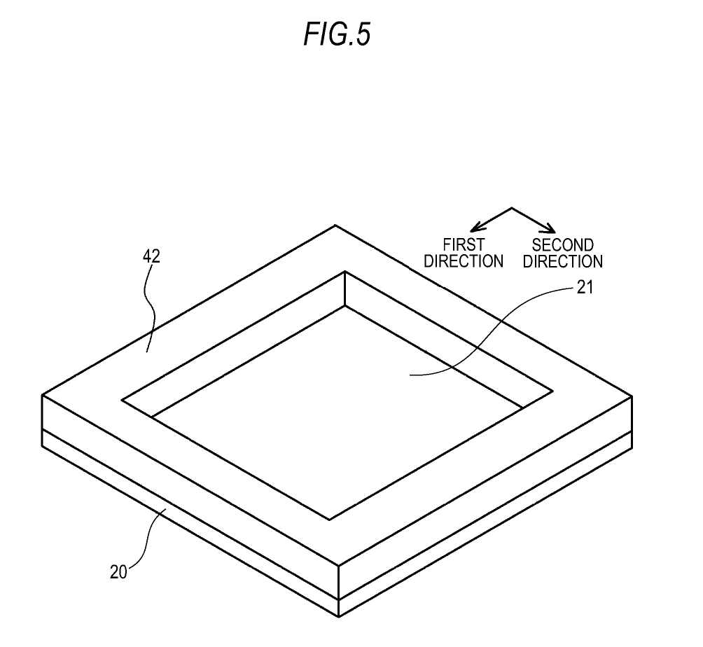

The fifth embodiment is a modification of the fourth embodiment. As shown in FIG. 5 by a schematic perspective view of the thin-film element assembly of the fifth embodiment as seen from the first surface side, in the thin-film element assembly of the fifth embodiment, an additional convex portion (first convex portion 42) is also formed in the second region of the first surface 21 of the base 20 along the two sides 20B and 20D extending in the second direction. That is, in the fifth embodiment, the convex portions (first convex portions 42) are provided in the second region of the first surface 21 of the base 20 in a frame shape so as to surround the first region. Except for this, since the configuration and structure of the thin-film element assembly of the fifth embodiment are the same as the configuration and structure of the thin-film element assembly described in the fourth embodiment, detailed description thereof is not provided.

### Sixth Embodiment

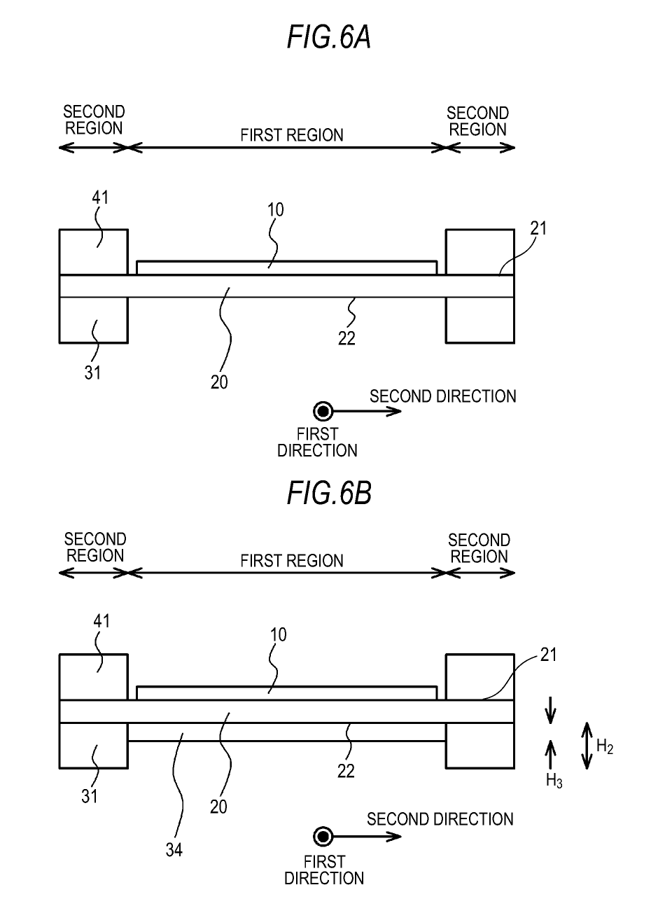

The sixth embodiment is a modification of the first and fourth embodiments or a modification of the third and fourth embodiments. As shown in FIG. 6A or FIG. 6B by a schematic side view of the thin-film element assembly of the sixth embodiment as seen from the first direction, in the thin-film element assembly of the sixth embodiment, the convex portion includes the first convex portion 41 of the fourth embodiment and the second convex portion 31 of the first embodiment. Except for this, since the configuration and structure of the thin-film element assembly of the sixth embodiment are the same as the configuration and structure of the thin-film element assembly described in the first, third, and fourth embodiments, detailed description thereof is not provided.

### Seventh Embodiment

In the seventh embodiment and the eighth to eleventh embodiments described below, the thin-film element will be described.

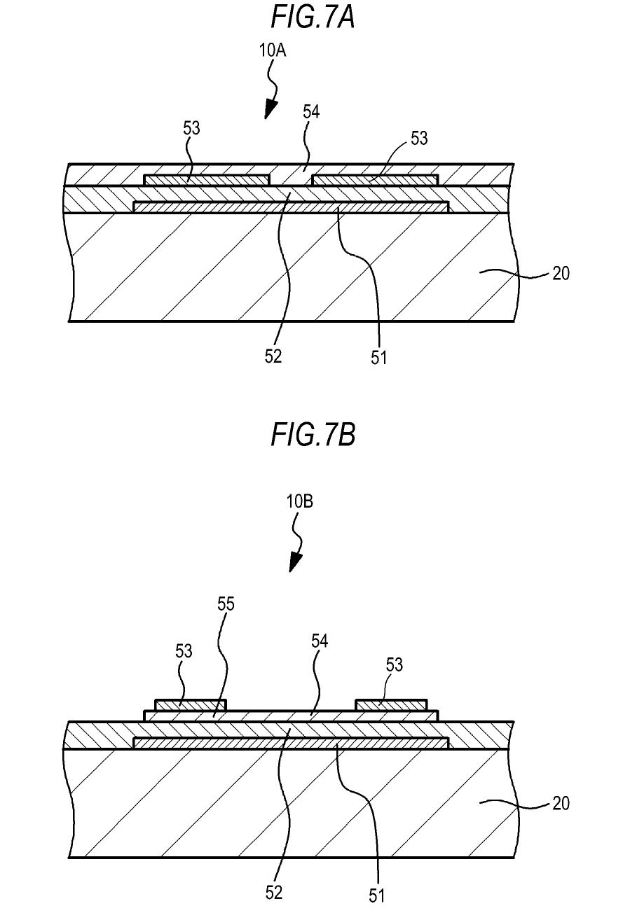

As shown in FIG. 7A by a schematic partial cross-sectional view, in the seventh embodiment, a thin-film element 10A includes:

a first electrode and a second electrode;

an active layer formed between the first electrode and the second electrode; and

a control electrode facing the active layer with an insulating layer interposed.

More specifically, the thin-film element assembly 10A is formed of a field-effect transistor (FET), specifically, a thin-film transistor (TFT),

the first and second electrodes correspond to source/drain electrodes 53,

the control electrode corresponds to a gate electrode 51,

the insulating layer corresponds to a gate insulating layer 52, and

the active layer corresponds to a channel forming region 54. Moreover, a current flowing into the active layer from the first electrode toward the second electrode is controlled by a voltage applied to the control electrode.

Here, the thin-film element 10A formed of the TFT is more specifically a bottom-gate and bottom-contact type TFT and includes:

(A) the gate electrode 51 (corresponding to the control electrode) formed on the base 20;

(B) the gate insulating layer 52 (corresponding to the insulating layer) formed on the gate electrode 51 and the base 20;

(C) the source/drain electrodes 53 (corresponding to the first and second electrodes) formed on the gate insulating layer 52; and

(D) the channel forming region 54 (corresponding to the active layer) formed of an organic semiconductor material layer, on the gate insulating layer 52 between the source/drain electrodes 53.

In the seventh to tenth embodiments, the control electrode (the gate electrode 51) and the first and second electrodes (the source/drain electrodes 53) are formed of gold (Au), the insulating layer (the gate insulating layer 52) is formed of SiO₂, and the active layer (the channel forming region 54) is formed of TIPS (triisopropylsilyl)-pentacene.

Hereinafter, a method of manufacturing the thin-film element of the seventh embodiment and a method of manufacturing an image display device are described. In the following description, the control electrode and the gate electrode will be collectively referred to as the gate electrode, the first and second electrodes and the source/drain electrodes will be collectively referred to as the source/drain electrodes, the insulating layer and the gate insulating layer will be collectively referred to as the gate insulating layer, and the active layer and the channel forming region will be collectively referred to as the channel forming region.

### [Step-700]

First, the gate electrode 51 is formed on the base 20. Specifically, a resist layer (not shown) in which a portion where the gate electrode 51 is to be formed is removed is formed on the base 20 based on a lithography technique. After that, a titanium (Ti) layer (not shown) as a contact layer and a gold (Au) layer as the gate electrode 51 are sequentially formed on the entire surface of the base by a vacuum evaporation method, and then, the resist layer is removed. In this way, the gate electrode 51 can be obtained based on a so-called lift-off method.

### [Step-710]

Subsequently, the gate insulating layer 52 is formed on the entire surface, specifically, of the base 20 including the gate electrode 51. Specifically, the gate insulating layer 52 formed of SiO₂ is formed on the gate electrode 51 and the base 20 based on a sputtering method. When forming the gate insulating layer 52, by covering a part of the gate electrode 51 with a hard mask, an extraction portion (not shown) of the gate electrode 51 can be formed without using a photolithography process.

### [Step-720]

After that, the source/drain electrodes 53 formed of a gold (Au) layer is formed on the gate insulating layer 52. Specifically, a titanium (Ti) layer (not shown) having a thickness of about 0.5 nm as a contact layer and a gold (Au) layer having a thickness of about 25 nm as the source/drain electrodes 53 are sequentially formed based on a vacuum evaporation method. When forming these layers, by covering a part of the gate insulating layer 52 with a hard mask, the source/drain electrodes 53 can be formed without using a photolithography process.

### [Step-730]

Subsequently, an organic semiconductor material solution is applied on at least the gate insulating layer 52 positioned between the source/drain electrodes 53 and dried, whereby the channel forming region 54 formed of the organic semiconductor material layer is formed. Here, the organic semiconductor material solution is prepared in advance. Specifically, one gram of TIPS-pentacene as an organic semiconductor material is dissolved into 100 grams of 1,2,3,4-tetrahydronaphthalene which is an organic solvent. Moreover, after the organic semiconductor material layer is formed by a spin coating method using the organic semiconductor material solution, the formed organic semiconductor material layer is dried under the conditions of 90° C. and 1 hour. In this way, the channel forming region 54 (the active layer) can be obtained.

Alternatively, after the organic semiconductor material layer is formed by an ink jet printing method using the above-described organic semiconductor material solution, by drying the formed organic semiconductor material layer under the conditions of 90° C. and 1 hour, the channel forming region 54 (the active layer) can be obtained.

### [Step-740]

After that, a passivation film (not shown) is formed on the entire surface, and wirings (not shown) connected to the gate electrode 51 and the source/drain electrodes 53 are formed. In this way, a bottom-gate and bottom-contact type FET (specifically, TFT) can be obtained (see FIG. 7A).

In manufacturing of an image display device, subsequent to this step, an image display unit (specifically, an image display unit formed of an organic electroluminescence element, a microcapsule-type electrophoretic display element, or a semiconductor light-emitting element, for example) may be formed on or above the thin-film element 10A based on a known method.

### Eighth Embodiment

The eighth embodiment is a modification of the seventh embodiment. In the eighth embodiment, a thin-film element 10B is formed of a bottom-gate and top-contact type FET (specifically, TFT). As shown by a schematic partial cross-sectional view in FIG. 7B, the field-effect transistor of the eighth embodiment includes:

(A) the gate electrode 51 (corresponding to the control electrode) formed on the base 20;

(B) the gate insulating layer 52 (corresponding to the insulating layer) formed on the gate electrode 51 and the base 20;

(C) the channel forming region 54 (corresponding to the active layer) and the channel forming region extension portion 55 formed of an organic semiconductor material layer, on the gate insulating layer 52; and

(D) the source/drain electrodes 53 (corresponding to the first and second electrodes) formed on the channel forming region extension portion 55.

Hereinafter, an overview of a method of manufacturing the thin-film element of the eighth embodiment will be described.

### [Step-800]

First, similarly to Step-700 to Step-710 of the seventh embodiment, the gate electrode 51 and the gate insulating layer 52 are formed on the base 20.

### [Step-810]

Subsequently, similarly to Step-730 of the seventh embodiment, by applying an organic semiconductor material solution on the gate insulating layer 52 and drying the applied organic semiconductor material solution, the channel forming region 54 and the channel forming region extension portion 55 formed of the organic semiconductor material layer are formed.

### [Step-820]

After that, the source/drain electrode 53 are formed on the channel forming region extension portion 55 so that the channel forming region 54 is interposed therebetween. Specifically, similarly to Step-720 of the seventh embodiment, a titanium (Ti) layer (not shown) as a contact layer and a gold (Au) layer as the source/drain electrodes 53 are sequentially formed based on a vacuum evaporation method. When forming these layers, by covering a part of the channel forming region extension portion 55 with a hard mask, the source/drain electrodes 53 can be formed without using a photolithography process.

### [Step-830]

Subsequently, formation of a passivation film (not shown) and formation of wirings (not shown) are performed similarly to the seventh embodiment, whereby the thin-film element 10B of the eighth embodiment can be obtained.

### Ninth Embodiment

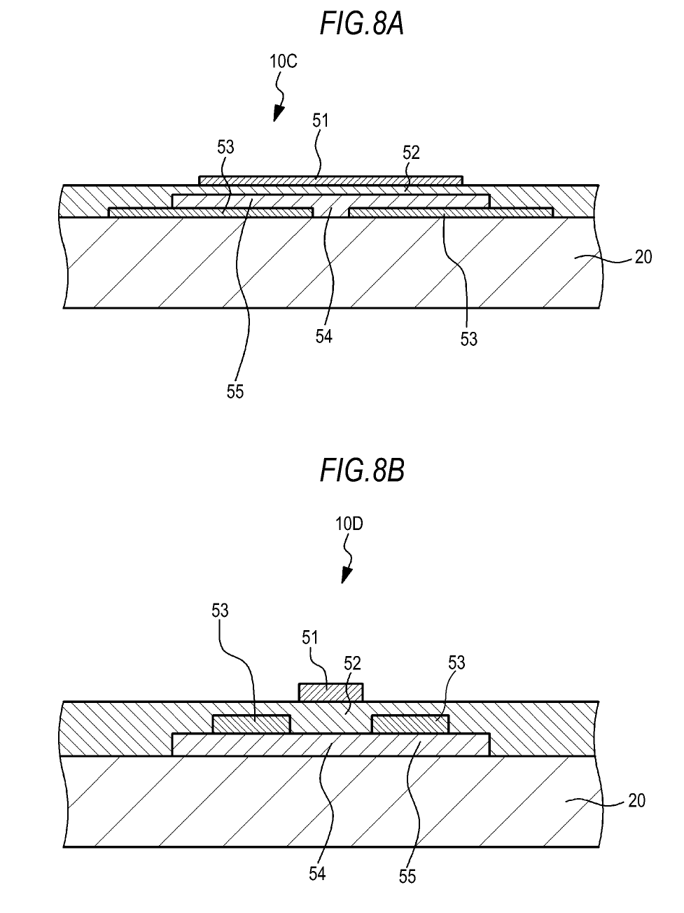

The ninth embodiment is also a modification of the seventh embodiment. In the ninth embodiment, a thin-film element 10C is formed of a top-gate and bottom-contact type FET (specifically, TFT). As shown by a schematic partial cross-sectional view in FIG. 8A, the field-effect transistor of the ninth embodiment includes:

(A) the source/drain electrodes 53 (corresponding to the first and second embodiments) formed on the base 20;

(B) the channel forming region 54 (corresponding to the active layer) formed of the organic semiconductor material layer, on the base 20 between the source/drain electrodes 53;

(C) the gate insulating layer 52 (corresponding to the insulating layer) formed on the channel forming region 54; and

(D) the gate electrode 51 (corresponding to the control electrode) formed on the gate insulating layer 52.

Hereinafter, an overview of a method of manufacturing the thin-film element of the ninth embodiment will be described.

### [Step-900]

First, after forming the source/drain electrodes 53 on the base 20 similarly to Step-720 of the seventh embodiment, by applying an organic semiconductor material solution on the entire surface, specifically, on the base 20 including the source/drain electrode 53 and drying the applied organic semiconductor material solution, similarly to Step-730 of the seventh embodiment, the channel forming region (the active layer) 54 formed of the organic semiconductor material layer is formed.

### [Step-910]

Subsequently, the gate insulating layer 52 is formed on the entire surface by the same method as Step-710 of the seventh embodiment. After that, the gate electrode 51 is formed in a portion of the gate insulating layer 52 on the channel forming region 54 by the same method as Step-700 of the seventh embodiment.

### [Step-920]

Subsequently, formation of a passivation film (not shown) and formation of wirings (not shown) are performed similarly to the seventh embodiment, whereby the thin-film element 10C of the ninth embodiment can be obtained.

### Tenth Embodiment

The tenth embodiment is also a modification of the seventh embodiment. In the tenth embodiment, a thin-film element 10D is formed of a top-gate and top-contact type FET (specifically, TFT). As shown by a schematic partial cross-sectional view in FIG. 8B, the field-effect transistor of the tenth embodiment includes:

(A) the channel forming region 54 (corresponding to the active layer) and the channel forming region extension portion 55 formed of the organic semiconductor material layer, on the base 20;

(B) the source/drain electrodes 53 (the first and second electrodes) formed on the channel forming region extension portion 55;

(C) the gate insulating layer 52 (corresponding to the insulating layer) formed on the source/drain electrodes 53 and the channel forming region 54; and

(D) the gate electrode 51 (corresponding to the control electrode) formed on the gate insulating layer 52.

Hereinafter, an overview of a method of manufacturing the thin-film element of the tenth embodiment will be described.

### [Step-1000]

First, by applying an organic semiconductor material solution on the base 20 and drying the applied organic semiconductor material solution similarly to Step-730 of the seventh embodiment, the channel forming region 54 and the channel forming region extension portion 55 formed of the organic semiconductor material layer are formed.

### [Step-1010]

Subsequently, the source/drain electrodes 53 are formed on the channel forming region extension portion 55 by the same method as Step-720 of the seventh embodiment.

### [Step-1020]

After that, the gate insulating layer 52 is formed on the entire surface by the same method as Step-710 of the seventh embodiment. Subsequently, the gate electrode 51 is formed in a portion of the gate insulating layer 52 on the channel forming region 54 by the same method as Step-700 of the seventh embodiment.

### [Step-1030]

Subsequently, formation of a passivation film (not shown) and formation of wirings (not shown) are performed similarly to the seventh embodiment, whereby the thin-film element 10D of the tenth embodiment can be obtained.

### Eleventh Embodiment

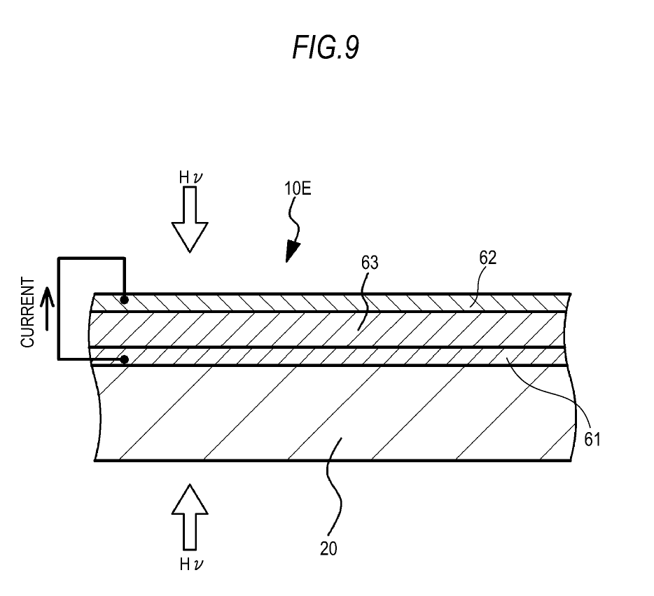

The eleventh embodiment is also a modification of the seventh embodiment. In the eleventh embodiment, a thin-film element 10E is formed specifically of a two-terminal device. More specifically, as shown in FIG. 9 by a schematic partial cross-sectional view, the thin-film element 10E includes:

a first electrode 61 and a second electrode 62; and

an active layer 63 formed between the first electrode 61 and the second electrode 62. The active layer 63 is formed of an organic semiconductor material. Moreover, electricity is generated by irradiation of the active layer 63 with light. That is, the thin-film element 10E of the eleventh embodiment functions as a photoelectric conversion element or a photovoltaic battery. Alternatively, the thin-film element 10E functions as a light-emitting element in which the active layer 63 emits light when a voltage is applied to the first and second electrodes 61 and 62.

Except for the above, since the configuration and structure of the thin-film element of the eleventh embodiment are the same as the configuration and structure of the thin-film element described in the seventh embodiment, detailed description thereof will not be provided. The thin-film element of the eleventh embodiment can be obtained by forming the first electrode 61, the active layer 63, and the second electrode 62 substantially similarly to Step-720, Step-730, and Step-720 of the seventh embodiment and forming wirings similarly to Step-740 of the seventh embodiment.

While the present disclosure has been described based on preferred embodiments, the present disclosure is not limited to these embodiments. The structure and configuration of the thin-film element assembly and the formation and manufacturing conditions thereof are exemplary and can be appropriately changed. In the embodiments, although the thin-film element is formed of a three-terminal device or a two-terminal device, the thin-film element may be formed of an organic electroluminescence element, a microcapsule-type electrophoretic display element, and a semiconductor light-emitting element having a known configuration and structure, for example. Moreover, the method of manufacturing these organic electroluminescence element, microcapsule-type electrophoretic display element, and semiconductor light-emitting element itself may employ a known manufacturing method.

In the embodiments, although the base is configured to have a single layer, a second base, and furthermore, a third base, a fourth base, and so on, formed of a different material (for example, the same material as the material constituting the convex portion) may be bonded to the second surface of the base. In some cases, by bonding a second base formed of a different material (for example, the same material as the material constituting the convex portion) to the second surface of the base, and processing the second base by etching, for example, a convex portion may be formed on the second surface of the base.

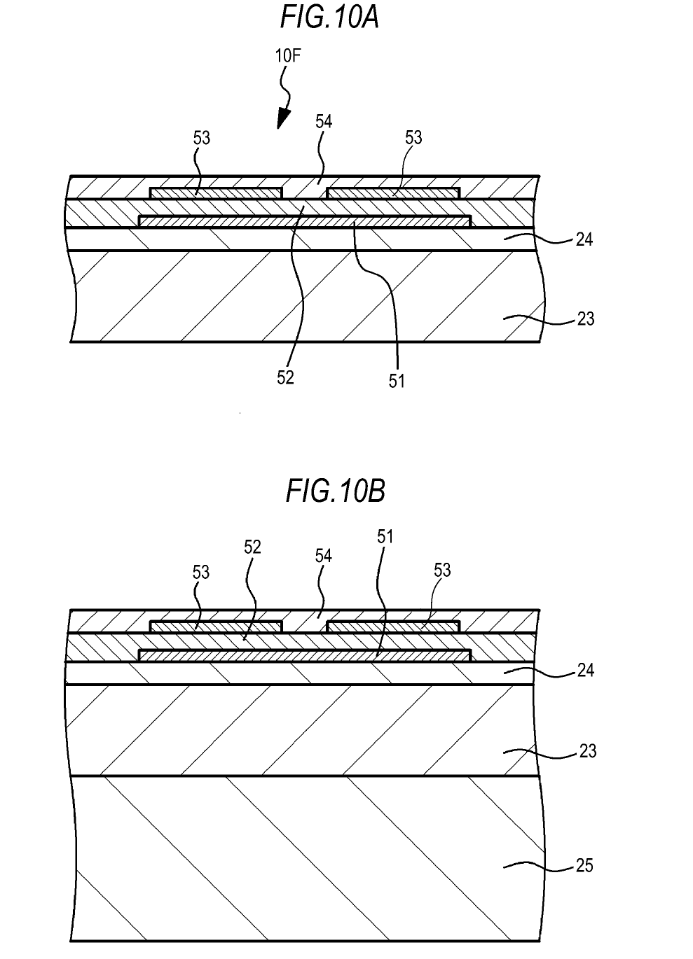

Alternatively, as shown in FIGS. 10A and 10B by a schematic partial cross-sectional view of a modification of the thin-film element assembly of the embodiment and a schematic partial cross-sectional view of a support substrate or the like for explaining a manufacturing method of a modification example of the thin-film element assembly of the embodiment, a support substrate 25 in which concave portions corresponding to convex portions is prepared. The thin-film element assembly can be manufactured based on the steps of:

forming a first base 23 formed of a resin material on the support substrate 25 by an application method;

forming a second base 24 formed of a resin curable by heat or irradiation of energy beams on the first base 23;

forming any one of the thin-film elements 10A to 10D (or the thin-film elements 10 and 10E) on the second base 24 (see FIG. 10B); and

separating the support substrate 25 from the first base 23 (see FIG. 10A). Here, when the support substrate 25 is separated from the first base 23, convex portions (second convex portions) are provided on the second surface of the first base 23 so as to correspond to concave portions provided on the support substrate 25. Moreover, the first surface of the first base 23 is bonded to the second surface of the second base 24, and the thin-film element is formed on the second surface of the second base 24. The glass transition temperature of the resin material constituting the first base 23 is preferably 180° C. or higher. Alternatively, the glass transition temperature of the resin material constituting the first base 23 is preferably higher than the highest temperature of the process temperature when forming the thin-film element. For example, the baking temperature of silver paste when forming wirings connected to the gate electrode and the source/drain electrodes based on printing and baking of the silver paste is the highest temperature (specifically, 150° C.) of the process temperature in a series of steps of manufacturing the thin-film element or the image display device. Alternatively, the thin-film element assembly may be manufactured based on the steps of:

forming the first base 23 formed of a non-crystalline thermoplastic resin on the support substrate 25 by an application method;

forming the second base 24 formed of a thermoplastic resin or an ultraviolet curable resin on the first base 23;

forming a thin-film element on the second base 24; and

separating the support substrate 25 from the first base 23.

As above, when the support substrate is separated from the first base after forming the thin-film element on a two-layered base of the first base and the second base, the thin-film element can be manufactured by a simple method without requiring a large manufacturing apparatus. Moreover, by forming the first base using a resin material described later, the first base can be reliably separated from the support substrate. Furthermore, since the thin-film element is formed on the second base in a state where the first base is covered with the second base, the occurrence of damages on the first base during formation of the thin-film element can be reliably prevented. Moreover, since the first base is formed on the support substrate by an application method, it is possible to easily form the first base and to prevent the occurrence of bubbles or the like between the support substrate and the first base.

A peel strength (specifically, 90° peel strength of bonded assemblies) to the support substrate is preferably 1.0 N/cm (0.1 kgf/cm) to 4.9 N/m (0.5 kgf/cm). The 90° peel strength of bonded assemblies is defined by the JIS K6854-1: 1999 standards. Specific examples of the resin material constituting the first base include polysulfone resin, polyethylsulfone resin, and polysulfoneimide resin. Specific examples of the material constituting the second base include thermoplastic resin such as epoxy-based resin and ultraviolet-curable resin. That is, specific examples of a preferred combination of the material constituting the first base and the material constituting the second base include polysulfone resin and epoxy-based resin, polyethylsulfone resin and epoxy-based resin, and polysulfoneimide resin and epoxy-based resin. In order to form the first base formed of a resin material on the support substrate, it is necessary to prepare a solution in which the resin material is dissolved. As a solvent, water; alcohols such as ethyl alcohol, isopropyl alcohol, and butyl alcohol; aromatic series such as toluene or xylene; ketones such as acetone or 2-butanone; hydrocarbons such as PGMEA can be used appropriately singly or as a mixture. Moreover, additives such as a surfactant or leveling agent may be added in addition to an organic solvent. Furthermore, materials other than a polymer material may be included depending on the purpose of providing an application performance or other properties, and specific examples thereof include a silica filler, a glass fiber, and the like. The resin material constituting the first base preferably does not chemically react with the support substrate. The support substrate is separated from the first base, which can be performed mechanically. Specifically, a snip may be inserted in the first and second bases on the support substrate using a machine or by hands, and the support substrate is separated from the first base, and alternatively, the first base may be separated from the support substrate using a machine or by hands. Alternatively, a snip may be inserted in the first and second bases on the support substrate using a machine or by hands, and water may be introduced into the snip, whereby the support substrate is separated from the first base, and alternatively, the first base is separated from the support substrate. The thickness of the first base may have such a thickness that the first base can reliably support the thin-film element and apply flexibility to the thin-film element as necessary. The thickness of the second base may have such a thickness that the second base can reliably protect the first base from a ketone-based solvent and apply flexibility to the thin-film element as necessary. Since the thin-film element is formed on the second base, the second base preferably has insulating properties. As a method of forming the second base on the first base, various application methods described above can be adopted. However, the method is not limited to the methods, and a method of preparing the sheet-like second base in advance and stacking the second base on the first base may be employed. Examples of the support substrate (support base) include various glass substrates, various glass substrates in which an insulating film is formed on the surface, a quartz substrate, a quartz substrate in which an insulating film is formed on the surface, a silicon substrate in which an insulating film is formed on the surface, a sapphire substrate, and a metal substrate formed of various metals and various alloys such as stainless steel.

The present disclosure contains subject matter related to that disclosed in Japanese Priority Patent Application JP 2011-107287 filed in the Japan Patent Office on May 12, 2011, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A thin-film element assembly comprising:
a base having flexibility and
a plurality of thin-film elements provided on a first surface of the base,
wherein a second region where no thin-film element is provided is formed in the base in an outer side of a first region where a plurality of thin-film elements are provided, and
wherein convex portions are formed in the second region of the first surface of the base, or the second region of a second surface, or the second region of each of the first and second surfaces.

2. The thin-film element assembly according to claim 1,
wherein the base has a rectangular shape such that two opposite sides extend in a first direction, and the other two opposite sides extend in a second direction, and
wherein the convex portions are formed in the second region along the two sides extending in the first direction.

3. The thin-film element assembly according to claim 2,
wherein the base is rollable about an axial line parallel to the second direction.

4. The thin-film element assembly according to claim 2,
wherein each of the convex portions has a notch portion extending in parallel to the second direction.

5. The thin-film element assembly according to claim 2,
wherein the convex portions are formed in the second region of the second surface of the base, or the second region of each of the first and second surfaces of the base,
wherein a reinforcing member extending in the second direction is formed in at least the first region of the second surface of the base, and
wherein the height of the reinforcing member is lower than the height of the convex portion formed in the second region of the second surface of the base.

6. The thin-film element assembly according to claim 2,
wherein the convex portions are formed in the second region of the first surface of the base or the second region of each of the first and second surfaces of the base, and
wherein additional convex portions are formed in the second region of the first surface of the base along the second sides extending in the second direction.

7. The thin-film element assembly according to claim 1,
wherein the convex portions are formed of at least one material selected from a group consisting of an expanded material, a gel-like material, and a rubber-like material.

8. The thin-film element assembly according to claim 7,
wherein the convex portions contain an antistatic agent.
